(19) United States
(12) Patent Application Publication
(10) Pub. No.: US 2019/0165330 A1
(43) Pub. Date: May 30, 2019

(54) EVAPORATION EQUIPMENT

(71) Applicants: BOE Technology Group Co., Ltd., Beijing (CN); HEFEI XINSHENG OPTOELECTRONICS TECHNOLOGY CO., LTD., Anhui (CN)

(72) Inventors: Kaihong Ma, Beijing (CN); Li Sun, Beijing (CN)

(21) Appl. No.: 15/984,640

(22) Filed: May 21, 2018

(30) Foreign Application Priority Data
Nov. 27, 2017 (CN) 201711213508.X

(51) Int. Cl. H01L 51/56; C23C 14/24; H01L 51/00

(52) U.S. Cl. CPC H01L 51/56; C23C 14/042; H01L 51/001; C23C 14/24

(57) ABSTRACT

In one embodiment, there is provided an evaporation equipment. The evaporation equipment includes: a plurality of evaporation sources for performing an evaporation on a substrate to be evaporated; and a partition for adjusting an evaporation range of each of the evaporation sources.

### CROSS-REFERENCE TO RELATED APPLICATION

This application claims priority to Chinese Patent Application No. 201711213508.X filed on Nov. 27, 2017 in the State Intellectual Property Office of China, the disclosure of which is hereby incorporated by reference in its entirety.

### TECHNICAL FIELD

The present disclosure relates to the field of display technology, and particularly, to an evaporation equipment.

### BACKGROUND

An OLED (Organic Light Emitting Diode) display device includes various organic functional material layers. At present, a mainstream technology for manufacturing an OLED device is to use evaporation equipment to perform an evaporation scanning on a substrate to be evaporated, to form various organic material functional layers of the OLED device.

Evaporation is a method of heating and plating a material onto a substrate under vacuum conditions. An evaporation equipment includes a plurality of evaporation sources, and the evaporation source forms an evaporation range of the organic material thereover by continuous heating. When the substrate passes over the evaporation source, the substrate is plated with the corresponding organic material. However, the existing evaporation equipment has technical problems such as low evaporation efficiency and complicated operation process for adjusting the mixing evaporation ratio, which limits the development of structure of the OLED device.

### SUMMARY

According to an aspect of the present disclosure, there is provided an evaporation equipment, and the evaporation equipment comprises: a plurality of evaporation sources for performing an evaporation on a substrate to be evaporated; and a partition for adjusting an evaporation range of each of the evaporation sources.

In some embodiments, the partition is provided between adjacent ones of the evaporation sources, a first end of the partition is provided on an evaporation surface of the evaporation source, and a second end, opposite to the first end, of the partition is extended to a surface to be evaporated of the substrate to be evaporated.

In some embodiments, the first end of the partition is provided with a first rotary mechanism capable of rotating the partition.

In some embodiments, the partition comprises a first sub-partition part located at the second end, and a cross-sectional area of the first sub-partition part gradually increases from the first end towards the second end.

In some embodiments, the first sub-partition part is provided with a heater.

In some embodiments, the first sub-partition part is integrated with the partition.

In some embodiments, a connection mechanism is provided on the evaporation surface between adjacent ones of the evaporation sources, and the first end of the partition is detachably connected with the connection mechanism.

In some embodiments, the first end of the partition is provided with a first rotary mechanism capable of rotating the partition, a connection mechanism is provided on the evaporation surface between adjacent ones of the evaporation sources, and the first end of the partition is detachably connected with the connection mechanism.

In some embodiments, the first rotary mechanism comprises a first rotary shaft located at a bottom of the connection mechanism.

In some embodiments, the first rotary mechanism comprises a first rotary shaft provided at the second end of the partition.

In some embodiments, a height of the partition is adjustable.

In some embodiments, the partition further comprises a plurality of second sub-partition parts removably connected in order.

In some embodiments, the partition further comprises a lower partition part and an upper partition part connected with each other, and the upper partition part is connected with the lower partition part through a lifting mechanism.

In some embodiments, a second rotary mechanism capable of rotating the evaporation source is provided at a bottom of the evaporation source and is configured to adjust an evaporation range of the evaporation source.

In some embodiments, the evaporation equipment further comprises a barrier board provided between adjacent ones of the evaporation sources, for separating the adjacent ones of the evaporation sources from each other.

In some embodiments, a top of the barrier board is connected with the first end of the partition.

### BRIEF DESCRIPTION OF THE DRAWINGS

FIG. 1 is a sectional view showing a structure of an evaporation equipment in related art;

FIG. 2 is a top view showing a structure of the evaporation equipment shown in FIG. 1;

FIG. 3 is a schematic view showing a structure of an evaporation equipment according to an embodiment of the present disclosure;

FIG. 4a is a schematic view showing a structure of an evaporation equipment according to another embodiment of the present disclosure;

FIG. 4b is a schematic view showing a structure of a connection mechanism in the evaporation equipment shown in FIG. 4a;

FIG. 5 is a schematic view showing a structure of an evaporation equipment according to yet another embodiment of the present disclosure;

FIG. 6 is a schematic view showing a structure of a first rotary mechanism in the embodiment shown in FIG. 5;

FIG. 7a is a schematic view showing a structure of an evaporation equipment according to still another embodiment of the present disclosure;

FIG. 7b is a schematic view showing a structure of a second sub-partition part in the evaporation equipment shown in FIG. 7a;

FIG. 7c is a schematic view showing an alternative structure of a partition in the embodiment shown in FIG. 7a;

FIG. 8 is a schematic view showing a structure of an evaporation equipment according to still yet another embodiment of the present disclosure; and

FIG. 9 is a schematic view showing a structure of an evaporation equipment according to a further embodiment of the present disclosure.

### DETAILED DESCRIPTION OF THE EMBODIMENTS

In order to provide a more clear understanding of objects, technique solutions and advantages of the present disclosure, a detailed description of embodiments of the present disclosure will be made as below in conjunction with the accompanying drawings. It should be noted that, these embodiments of the present disclosure and features described in these embodiments may be combined freely without involving any conflictions.

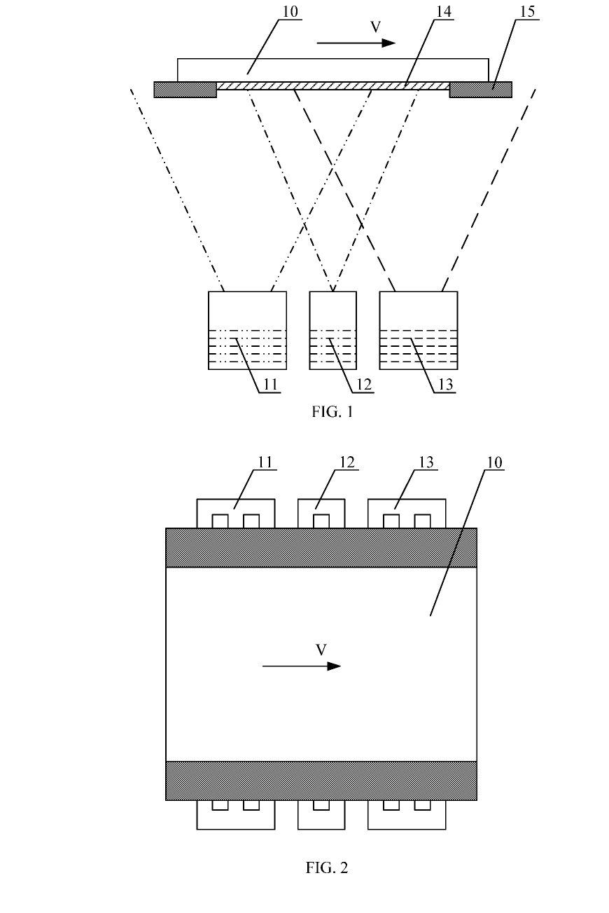

FIG. 1 is a sectional view showing a structure of an evaporation equipment in related art, and FIG. 2 is a top view showing a structure of the evaporation equipment shown in FIG. 1. The evaporation equipment, shown in FIG. 1 and FIG. 2, comprises three adjacent evaporation sources, namely, a first evaporation source 11, a second evaporation source 12 and a third evaporation source 13. A substrate to be evaporated (shorten as “substrate” hereinafter) 10 is located above the three evaporation sources 11, 12 and 13, and the substrate 10 moves at a velocity V in a direction indicated by the arrow. FIG. 1 and FIG. 2 only schematically show three evaporation sources. It should be understood by those skilled in the art that the evaporation equipment is not limited to including three evaporation sources.

It has been found by the inventor after researching that, in the evaporation process, the three evaporation sources 11, 12 and 13 simultaneously form an effective evaporation range of the organic material thereover by continuous heating, to ensure that the substrate 10 can be simultaneously plated with three kinds of organic materials, and thus to form a evaporated device 14 on the substrate 10, while a non-evaporated region is shielded by a mask 15. Of course, in the case where two of the evaporation sources perform a mixed evaporation, the substrate 10 can be simultaneously plated with two kinds of organic materials. However, due to complexity of the structural design of the evaporation source in the related art, the adjacent evaporation sources can only realize common evaporation of the three evaporation sources, a mixed evaporation of any two of the three evaporation sources, or an individual evaporation of any one of the three evaporation sources. The combined use of the evaporation sources is simple, and cannot realize diversity of use of the evaporation sources. Therefore, the use of the evaporation equipment in the related art has a great limitation. For example, when it is required to form three functional layers of different single materials simultaneously, the three evaporation sources each can only perform an individual evaporation, and the production efficiency is low. In addition, for a doped layer, the evaporation equipment in the related art can only adopt a method of adjusting linear evaporation sources when a mixing evaporation ratio of these materials needs to be changed, and the operation is complicated and the adjustment time is long.

In order to solve the problems in the related art that the production efficiency of the evaporation equipment is low, the operation process for adjusting the mixing evaporation ratio is complicated, and the like, according to embodiments of the present disclosure, there is provided an evaporation equipment. The evaporation equipment includes a plurality of evaporation sources for performing an evaporation on a substrate. And the evaporation equipment also includes a partition for adjusting an evaporation range of each of the evaporation sources.

The evaporation equipment according to embodiments of the present disclosure, not only includes the plurality of evaporation sources for performing an evaporation on a substrate, but also includes the partition for adjusting an evaporation range of each of the evaporation sources. When individual evaporations are required to be performed simultaneously, the partition is provided between adjacent evaporation sources to separate the adjacent evaporation sources, thereby achieving the individual evaporations simultaneously. When a mixing evaporation is required to be performed, the partition is removed. When a mixing evaporation ratio is required to be changed, the partition is rotated or a height of the partition is adjusted. In short, by provision of the partition for adjusting an evaporation range of each of the evaporation sources, the evaporation equipment according to embodiments of the present disclosure improves its production efficiency, simplifies the operation process of adjusting the mixing evaporation ratio, and realizes the diversity of use of the evaporation sources, which facilitates the development of structure of the evaporated device. Particularly when the input cost of the equipment is limited, the partition may be installed on the evaporation equipment in the related art by referring to the solution according to the embodiments of the present disclosure, to solve the problem of insufficient quantity of the evaporation sources, making the evaporation source function fully, effectively saving the cost, and developing a variety of structures of the evaporated device.

Technical solutions according to the embodiments of the present disclosure will be described in detail below in conjunction with the attached drawings.

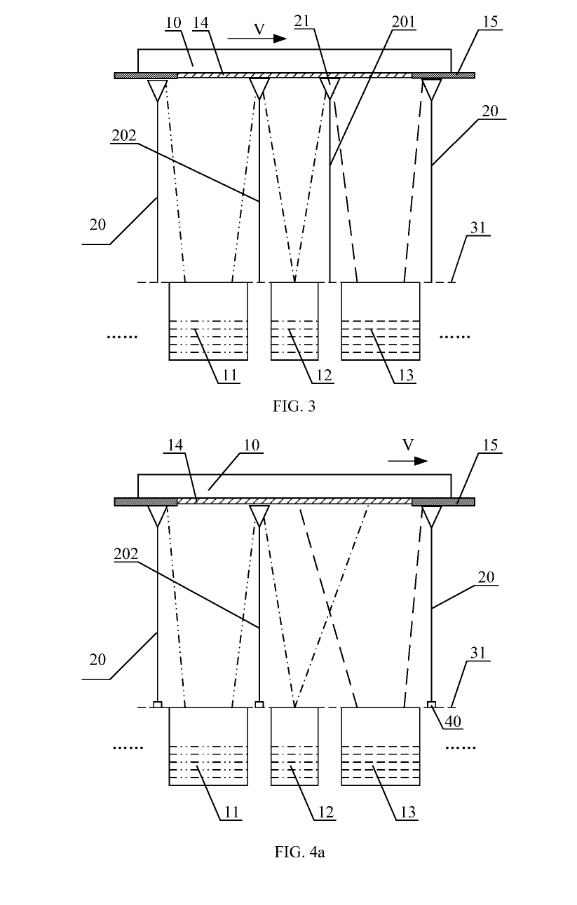

FIG. 3 is a schematic view showing a structure of an evaporation equipment according to an embodiment of the present disclosure. As seen from FIG. 3, the evaporation equipment comprises a plurality of evaporation sources for performing an evaporation on a substrate 10. In this embodiment, the substrate 10 moves at a velocity V in a direction indicated by the arrow. In this embodiment, a first evaporation source 11, a second evaporation source 12 and a third evaporation source 13 are provided in that order, and different organic materials are set in the three evaporation sources, respectively. The evaporation source releases the organic material gas upwards, to form an evaporated device 14 on the substrate 10. A non-evaporated region of the substrate 10 is shielded by a mask 15. The mask plate 15 moves together with the substrate 10. The evaporation equipment also includes partitions 20, 201 and 202 for adjusting an evaporation range of each of the evaporation sources.

In this embodiment, different organic materials are set in the three evaporation sources, respectively. However, it should be understood that the material for evaporation in the evaporation source is not limited to the organic material, and selection of the material for evaporation can be determined according to practical requirements.

By provision of the partitions 20, 201 and 202 for adjusting evaporation ranges of the evaporation sources, evaporation ranges of the evaporation sources of the evaporation equipment according to embodiments of the present disclosure can be adjusted, to achieve the evaporated devices 14 of different structures. The evaporation equipment realizes the diversity of use of the evaporation sources, increases production efficiency, and facilitates the development of structure of the evaporated device.

In the embodiment shown in FIG. 3, top surfaces of the evaporation sources 11, 12 and 13 form an evaporation surface 31. The partitions 20, 201, 202 are provided between adjacent evaporation sources, respectively. First ends of the partitions 20, 201, 202 are provided on an evaporation surface 31 of the evaporation sources 11, 12 and 13, and second ends of the partitions 20, 201, 202 are extended to a surface to be evaporated of the substrate 10. In the embodiment, as shown in FIG. 3, a left partition 20 and a partition 202 are provided at both sides of the evaporation source 11, respectively, partitions 202, 201 are provided at both sides of the evaporation source 12, respectively, and a partition 201 and a right partition 20 are provided at both sides of the evaporation source 13, respectively, so that evaporation ranges of the three evaporation sources 11, 12 and 13 are separated from each other. The evaporation equipment in the related art, due to lack of the partitions 20, 201 and 202, can only perform one evaporation of a single material functional layer on the substrate at one time. When it is required to form three functional layers of different single materials on the substrate 10, three times of evaporations are needed. The evaporation equipment according to embodiments of the present disclosure achieves three individual evaporations simultaneously since the evaporation ranges of the three evaporation sources are separated from each other, accordingly, three functional layers of different single materials can be obtained on the substrate 10 at one time. Only one evaporation process is needed, which improves production efficiency of the evaporation equipment.

Herein, in order for convenience of the description below, the partition between the second evaporation source 12 and the third evaporation source 13 is referred to as a first partition 201, and the partition between the second evaporation source 12 and the first evaporation source 11 is referred to as a second partition 202.

When evaporation is performed using the evaporation source, the evaporation source releases organic material vapors upwards. Vaporization of organic material during the evaporation is similar to gas diffusion. Accordingly, although the second ends of the partitions 20, 201 and 202 are extended to the surface to be evaporated of the substrate 10, when individual evaporations are performed using the adjacent evaporation sources, the organic materials evaporated by the adjacent evaporation source may still mix at the second ends of the partitions, resulting in mixed evaporation or color mixture. In order to eliminate mixed evaporation or color mixture, the partition comprises a first sub-partition part located at the second end, and a cross-sectional area of the first sub-partition part gradually increases from the first end towards the second end. For example, a first sub-partition part 21 is located at the second end of the first partition 201, and the cross-sectional area of the first sub-partition part 21 gradually increases from the first end toward the second end. When the organic material vapors released by the second evaporation source 12 and the third evaporation source 13 reach the first sub-partition part 21, the organic material vapors at both sides of the first sub-partition part 21 are deposited on both sides of the first sub-partition part 21, preventing the overlap of the evaporation ranges at both sides of the first sub-partition part 21, avoiding the mixing evaporation or the color mixture at the second end of the first partition 201, and ensuring the performance of the evaporated device 14.

In the embodiment shown in FIG. 3, the cross section of first sub-partition part is triangular, and it is easy to understand that the cross section of first sub-partition part may have other shapes such as a semicircular shape. In other embodiments, the first sub-partition part may be integrated with the partition. The cross-sectional area of the integral partition gradually increases from the first end toward the second end.

In order to facilitate maintenance of the partition, the first sub-partition part may be provided with a heater. This reduces deposition of the organic material at the top of the partition and reduces difficulty of maintenance of the partition.

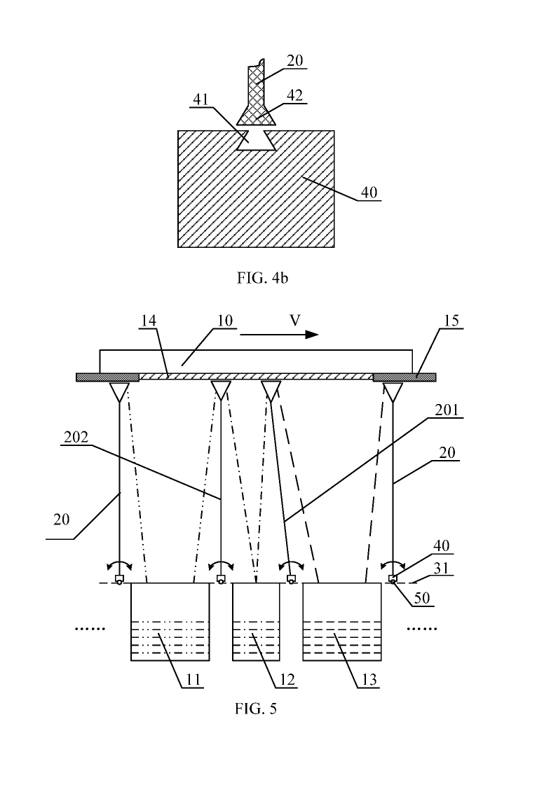

FIG. 4a is a schematic view showing a structure of an evaporation equipment according to another embodiment of the present disclosure. This embodiment is an extension example of the embodiment shown in FIG. 3, and a main structure of this evaporation equipment is basically the same as that in the embodiment shown in FIG. 3. Different from the embodiment shown in FIG. 3, in this embodiment, the first end of the partition 20 is detachably connected to the evaporation surface 31 of the evaporation source.

As seen from FIG. 4a, a connection mechanism 40 is provided on the evaporation surface 31 between adjacent evaporation sources, and the first end of the partition 20 is detachably connected with the connection mechanism 40. FIG. 4b is a schematic view showing a structure of the connection mechanism 40. An upper part of the connection mechanism 40 is provided with a first engaging groove 41, the first end of the partition 20 is provided with a first engaged part 42, and the first engaged part 42 and the first engaging groove 41 are engaged with each other, to detachably connect the partition 20 with the connection mechanism 40. This engagement is simply in structure and is easy in detachment. FIG. 4b shows a structure that one element is inserted in another element, that is, the first engaged part 42 is inserted in the first engaging groove 41 to achieve the engagement between the two. It is easy to understand that other types of engagements may also be designed. For example, the first engaged part 42 may be inserted in the first engaging groove 41 in a vertical direction to achieve an engagement between them; similarly, a detachable screw connection may also be used.

In FIG. 4a, the first partition 201 between the second evaporation source 12 and the third evaporation source 13 is removed, and evaporation ranges of the second evaporation source 12 and the third evaporation source 13 are overlapped with each other, in order to evaporate a doped layer consisted of first organic material and second organic material on a corresponding region of the substrate 10. While, the first evaporation source 12 performs an individual evaporation, to evaporate a single material functional layer on the substrate 10. With the evaporation equipment in related art, two evaporation processes are required to evaporate a single material functional layer and a doped layer on the substrate 10. However, with the evaporation equipment according to embodiments of the present disclosure, due to provision of the partitions 20 as needed, one evaporation process is required to evaporate a single material functional layer and a doped layer, improving the production efficiency of the evaporation equipment.

In the evaporation equipment according to embodiments of the present disclosure, the partition is detachably connected between the evaporation sources, and the partition can be provided as needed, improving the production efficiency of the evaporation equipment, achieving the use variety of the evaporation source, and facilitating development of the structure of the evaporated device.

FIG. 5 is a schematic view showing a structure of an evaporation equipment according to yet another embodiment of the present disclosure. This embodiment is an extension example of the embodiment shown in FIG. 4, and a main structure of this evaporation equipment is basically the same as that in the embodiment shown in FIG. 4. Different from the embodiment shown in FIG. 4, in this embodiment, the partition is rotatable.

As seen from FIG. 5, the first end of the partition 20 is provided with a first rotary mechanism 50 capable of rotating the partition 20. FIG. 6 is a schematic view showing a structure of the first rotary mechanism in the embodiment of FIG. 5. As seen from FIG. 6, the first rotary mechanism 50 comprises a first rotary shaft 51 located at a bottom of the connection mechanism 40. The first rotary shaft 51 is driven by a motor to rotate the partition 20 through the connection mechanism 40, so as to adjust an evaporation range of the evaporation source. It is easy to understand that, the first rotary mechanism 50 may also be directly provided at the first end of the partition 20, so that the first rotary mechanism 50 can directly rotate the partition 20.

In FIG. 5, the first partition 201 is rotated to the left by a certain angle so that the evaporation range of the second evaporation source 12 becomes smaller, and the evaporation range of the third evaporation source 13 becomes larger. Accordingly, the time for the substrate 10 to pass through the evaporation range of the second evaporation source 12 is shortened, so that a thickness of the functional layer of the corresponding second organic material on the substrate 10 is reduced; and the time for the substrate 10 to pass through the evaporation range of the third evaporation source 13 is extended, so that a thickness of the functional layer of the corresponding third organic material on the substrate 10 is increased. Compared with the embodiment shown in FIG. 3, after the first partition 201 is rotated, a thickness of the corresponding single material functional layer of the evaporated device 14 is changed, changing the structure of the evaporated device 14.

The evaporation equipment according to embodiments of the present disclosure can set a rotation angle of the partition as needed to obtain evaporated devices with different structures, further improve the use diversity of the evaporation source, and improve the development of structure of the evaporated device.

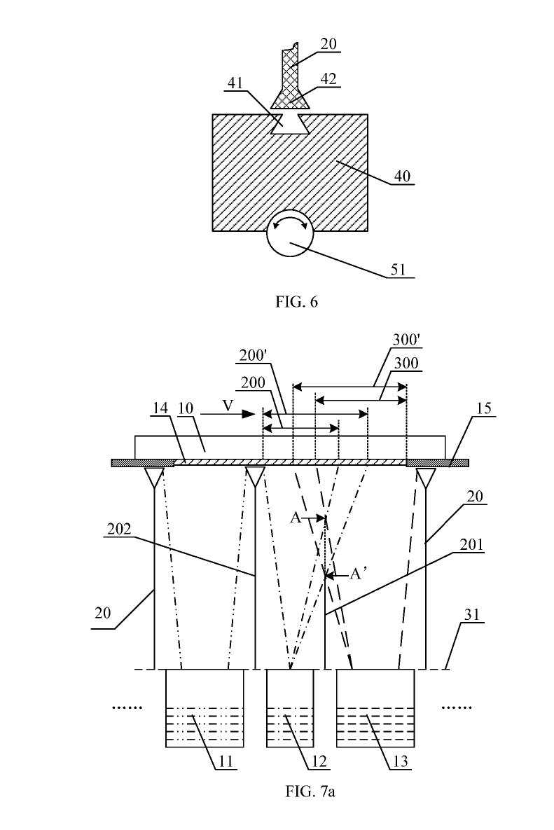

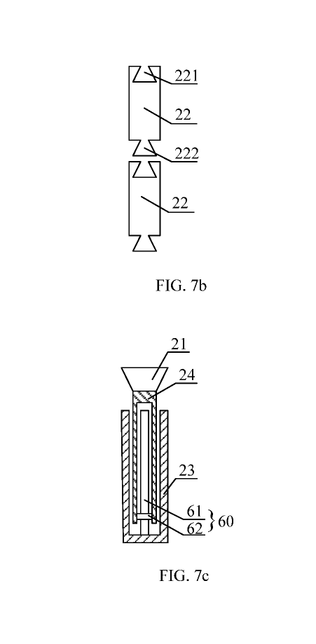

FIG. 7a is a schematic view showing a structure of an evaporation equipment according to still another embodiment of the present disclosure. This embodiment is an extension example of the embodiment shown in FIG. 3, and a main structure of this evaporation equipment is basically the same as that in the embodiment shown in FIG. 3. Different from the embodiment shown in FIG. 3, in this embodiment, a height of the partition is adjustable.

In FIG. 7a, provision of the second partition 202 makes the first evaporation source 11 perform an individual evaporation. By adjusting the height of the first partition 201, evaporation ranges of the second evaporation source 12 and the third evaporation source 13 on the substrate 10 can be adjusted. As seen from FIG. 7a, the height of the first partition 201 is adjusted so that a top of the first partition 201 is located at a position A. Here, the evaporation ranges of the second evaporation source 12 and the third evaporation source 13 are overlapped with each other, so that a doped layer consisted of the first organic material and the second organic material can be evaporated on the substrate 10. When the height of the first partition 201 is adjusted so that the top of the first partition 201 is moved from A to A′, the evaporation range of the second evaporation source 12 is changed from 200 to 200′, and the evaporation range of the third evaporation source 13 is changed from 300 to 300′. That is, the evaporation ranges of both the second evaporation source 12 and the third evaporation source 13 are changed, such that a mixing ratio of the first organic material and the second organic material in the doped layer is changed, namely, a mixing evaporation ratio of the doped layer is changed. Accordingly, the obtained evaporated devices 14 have different structures when the top of the first partition 201 is located at A and A′, respectively.

In the evaporation equipment according to the embodiment of the present disclosure, the evaporation range of the corresponding evaporation source is controlled by adjusting the height of the partition, so as to control a material mixing ratio of the doped layer and further expand the structure of the evaporated device.

In order to realize the adjustable height of the partition, in this embodiment, the partition further comprises a plurality of second sub-partition parts 22 connected in order, and the adjacent second sub-partition parts 22 are connected by engagements. FIG. 7b is a schematic view of a structure of the second sub-partition part 22. As seen from FIG. 7b, a second engaging groove 221 is provided at one end of each second sub-partition part 22, and a second engaged part 222 matching the second engaging groove 221 is provided at the other end of the each second sub-partition part 22. The second engaging groove 221 of a second sub-partition part 22 and the second engaged part 222 of an adjacent second sub-partition part 22 are engaged with each other, so that the plurality of second sub-partition parts 22 are connected in order. In this way, the height of the partition can be adjusted by changing quantity of the second sub-partition parts 22. The cross sections of the second engaging groove 221 and the second engaged part 222 shown in FIG. 7b are triangular, and the second engaged part 222 can be inserted into the second engaging groove 221 to achieve the engagement. It is easy to understand that the cross-sections of the two may also be in other shapes, and the engagement between the second engaging groove and the second engaged part is also not limited to the insertion manner, and an engagement structure in which the first engaged part 42 may be inserted in the first engaging groove 41 in a vertical direction for top-bottom plug-in snap connection may also be designed as needed.

FIG. 7c is a schematic view showing an alternative structure of the partition in the embodiment of FIG. 7a. As shown in FIG. 7c, the partition may further comprise a lower partition part 23 and an upper partition part 24 connected to each other. The upper partition part 24 is connected to the lower partition part 23 by a lifting mechanism 60. The lifting mechanism 60 comprises a screw nut 62 and a screw rod 61 fitted in the screw nut 62, and further includes a motor for driving rotation of the screw rod 61, and the screw nut 62 is fixed on the upper partition part 24 and the screw rod 61 is fixed on the lower partition part 23. The screw rod 61 is driven by the motor to rotate so as to drive the upper partition part 24 to rise and lower, to adjust the height of the partition. In FIG. 7c, both the screw rod 61 and the screw nut 62 are disposed inside the partition 20. It is easy to understand that the screw rod and the screw nut may also be disposed on the side of the partition 20.

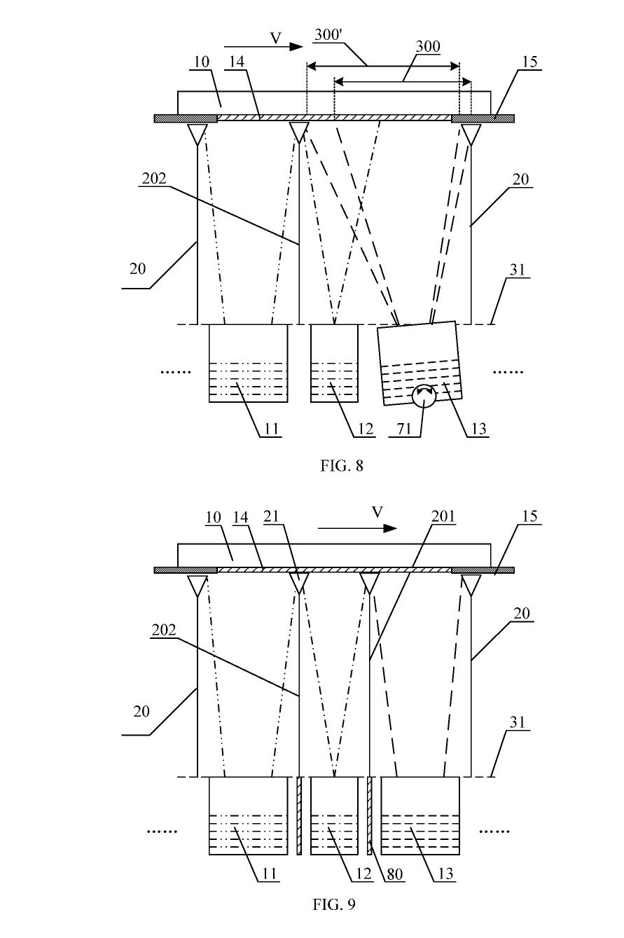

FIG. 8 is a schematic view showing a structure of an evaporation equipment according to still yet another embodiment of the present disclosure. This embodiment is an extension example of the embodiment shown in FIG. 4a, and a main structure of this evaporation equipment is basically the same as that in the embodiment shown in FIG. 4a. Different from the embodiment shown in FIG. 4a, in this embodiment, the evaporation source is rotatable for adjusting its evaporation range.

As shown in FIG. 8, a second rotary mechanism capable of rotating the evaporation source is provided at a bottom of the evaporation source 13. The second rotary mechanism comprises a second rotary shaft 71 at the bottom of the evaporation source 13 and a motor for driving a rotation of the second rotary shaft 71. Under the action of the motor, the second rotary shaft 71 rotates the evaporation source, to adjust the evaporation range of the evaporation source. In FIG. 8, the second rotary mechanism is provided at a bottom of the third evaporation source 13. When the third evaporation source 13 is rotated by a certain angle from the horizontal position to the left by the second rotary mechanism, the evaporation range of the third evaporation source 13 is changed from 300 to 300′. In this way, the mixing ratio of the first organic material and the second organic material of the doped layer is changed, that is, the mixing evaporation ratio of the doped layer is changed, and the structure of the evaporated device 14 is changed. It is easy to understand that although it is not shown in the figure, the bottoms of the first evaporation source 11 and the second evaporation source 12 may also be provided with rotary shafts to meet different requirements.

In the evaporation equipment according to the embodiments of the present disclosure, the evaporation range of the evaporation source can be controlled by adjusting a rotation angle of the corresponding evaporation source, thereby controlling the material mixing ratio of the doped layer and further expanding the structure of the evaporated device.

The feature that the evaporation source is rotatable according to the present embodiment may be combined with the feature according to any of the above embodiments so that the rotation angle of the evaporation source can also be adjusted while adjusting the height or/and the rotation angle of the partition. As a result, an axial direction of a nozzle of the evaporation source corresponds to the center of the evaporation range, to increase the uniformity of the thickness of the evaporated film.

In the use of the evaporation equipment, a heater inside the evaporation source heats the organic material therein to form an organic material vapor. Although the organic material vapor is released upwards, some of the vapors are still mixed through a gap between adjacent evaporation sources, and, in actual practice, heating interference occurs between adjacent evaporation sources. FIG. 9 is a schematic view showing a structure of an evaporation equipment according to a further embodiment of the present disclosure. This embodiment is an extension example of the embodiment shown in FIG. 3, and a main structure of the evaporation equipment is basically the same as that in the embodiment shown in FIG. 3.

Different from the embodiment shown in FIG. 3, in this embodiment, the evaporation equipment further comprises barrier boards 80 provided between adjacent evaporation sources 11, 12 and 13. The barrier boards 80 separate adjacent evaporation sources from each other, to prevent heating interference between the adjacent evaporation sources. Meanwhile, when replacing organic materials for the evaporation source, interference from adjacent evaporation sources may not occur, preventing crosstalk pollution between the organic materials, while eliminating the mixing of organic material vapors between adjacent evaporation sources, thereby ensuring evaporation effect.

As seen from FIG. 9, the top of the barrier board 80 may be connected with the first end of the partition 20. As a result, the connection mechanism 40 or the first rotary mechanism 50 in the abovementioned embodiments may be provided at the top of the barrier board 80, which simplifies structure of the evaporation equipment.

In the description of the embodiments of the present disclosure, it should be noted that, orientations or positional relationships denoted by terminologies “upper”, “lower”, “inner”, “outer” and the likes are those shown in the figures, and only intended for easing or simplifying the description of embodiments of the present disclosure, instead of expressing or implying that the devices or elements should be located at specific orientations or should be configured or manipulated at specific orientations, accordingly, they are not intended to limit the scope of the present disclosure.

In the description of the embodiments of the present disclosure, it should be noted that, unless otherwise specified and defined definitely, terminologies “mount”, “connect to”, “connect with” and the likes should be construed in a broad sense, for example, it may be a fixed connection, or a detachable connection, or an integrated connection; or, it may also be a mechanical connection or an electrical connection; or else, it may be a direct connection or an indirect connection with an intermediate agency or a communication between two elements. For those skilled in the art, the above terminologies may be construed in specific situations in the present disclosure.

Although the disclosed embodiments of the present disclosure have been shown and described as above, the contents described are merely embodiments for facilitating the understanding of the present disclosure and are not intended to limit the present disclosure. It will be apparent, however, for those skilled in the art that modifications and changes on the forms and details may be made in these embodiments without departing from the principles and spirit of the present disclosure, the scope of which is defined in the attached claims.

What is claimed is:

1. An evaporation equipment, comprising:
a plurality of evaporation sources for performing an evaporation on a substrate to be evaporated; and
a partition for adjusting an evaporation range of each of the evaporation sources.

2. The evaporation equipment of claim 1, wherein the partition is provided between adjacent ones of the evaporation sources, a first end of the partition is provided on an evaporation surface of the evaporation source, and a second end, opposite to the first end, of the partition is extended to a surface to be evaporated of the substrate to be evaporated.

3. The evaporation equipment of claim 2, wherein the first end of the partition is provided with a first rotary mechanism capable of rotating the partition.

4. The evaporation equipment of claim 2, wherein the partition comprises a first sub-partition part located at the second end, and a cross-sectional area of the first sub-partition part gradually increases from the first end towards the second end.

5. The evaporation equipment of claim 4, wherein the first sub-partition part is provided with a heater.

6. The evaporation equipment of claim 4, wherein the first sub-partition part is integrated with the partition.

7. The evaporation equipment of claim 2, wherein a connection mechanism is provided on the evaporation surface between adjacent ones of the evaporation sources, and the first end of the partition is detachably connected with the connection mechanism.

8. The evaporation equipment of claim 2, wherein the first end of the partition is provided with a first rotary mechanism capable of rotating the partition, a connection mechanism is provided on the evaporation surface between adjacent ones of the evaporation sources, and the first end of the partition is detachably connected with the connection mechanism.

9. The evaporation equipment of claim 8, wherein the first rotary mechanism comprises a first rotary shaft located at a bottom of the connection mechanism.

10. The evaporation equipment of claim 8, wherein the first rotary mechanism comprises a first rotary shaft provided at the second end of the partition.

11. The evaporation equipment of claim 2, wherein a height of the partition is adjustable.

12. The evaporation equipment of claim 11, wherein the partition further comprises a plurality of second sub-partition parts removably connected in order.

13. The evaporation equipment of claim 11, wherein the partition further comprises a lower partition part and an upper partition part connected with each other, and the upper partition part is connected with the lower partition part through a lifting mechanism.

14. The evaporation equipment of claim 1, wherein a second rotary mechanism capable of rotating the evaporation source is provided at a bottom of the evaporation source and is configured to adjust an evaporation range of the evaporation source.

15. The evaporation equipment of claim 1, further comprising a barrier board provided between adjacent ones of the evaporation sources, for separating the adjacent ones of the evaporation sources from each other.

16. The evaporation equipment of claim 9, wherein a top of the barrier board is connected with the first end of the partition.
